(19) United States
(12) Patent Application Publication
(10) Pub. No.: US 2026/0223695 A1
(43) Pub. Date: Jul. 30, 2026

(54) SEMICONDUCTOR DEVICE

(71) Applicant: ROHM CO., LTD., Kyoto-shi (JP)

(72) Inventors: Takahiro NEGORO, Kyoto-shi (JP); Taro NISHIOKA, Kyoto-shi (JP)

(21) Appl. No.: 19/573,536

(22) Filed: Mar. 20, 2026

Related U.S. Application Data
(63) Continuation of application No. PCT/JP2024/032031, filed on Sep. 6, 2024.

(30) Foreign Application Priority Data
Sep. 27, 2023 (JP) 2023-164094

(51) Int. Cl. H10W 70/40; H10W 74/10; H10W 90/00; H10W 90/10; H10W 72/00

(52) U.S. Cl. CPC H10W 70/429; H10W 74/114; H10W 90/10; H10W 90/756; H10W 90/811; H10W 72/884; H10W 90/736; H10W 90/753

(57) ABSTRACT

A semiconductor device includes a lead with a pad portion having a mount surface facing in a thickness direction, a semiconductor element on the mount surface, a wire bonded to the semiconductor element and the mount surface, and a sealing resin covering the semiconductor element, the wire, and a part of the pad portion. The wire includes a first bonding portion bonded to the semiconductor element and a second bonding portion bonded to the mount surface. The wire is provided with a protrusion overlapping the second bonding portion and being covered by the sealing resin. The pad portion is formed with a hole disposed closer to the second bonding portion than to the first bonding portion. The hole extends to penetrate through the pad portion in the thickness direction. A part of the sealing resin is disposed in the hole.

### TECHNICAL FIELD

The present disclosure relates to a semiconductor device

### BACKGROUND ART

The semiconductor device disclosed in JP-A-2016-207714 includes two die pads, a control element (controller) mounted on one of the die pads, a drive element (gate driver) mounted on the other die pad, and a sealing resin covering the control element and the drive element. The semiconductor device drives switching elements such as IGBTs and MOSFETs. The semiconductor device is used, for example, in an inverter circuit, for example.

The conventional semiconductor device further includes a lead connected to one of the two die pads and a bonding wire bonded to the lead. The bonding wire is covered with the sealing resin. The bonding wire is electrically connected to the control element or the drive element. In order to shorten the length of the bonding wire, the bonding wire can be electrically bonded to the die pad. In this case, the sealing resin is partitioned into upper and lower parts in the thickness direction by the die pad. This configuration raises the concern that the bonding wire may easily be detached from the die pad due to the reduced thickness of the upper part of the sealing resin covering the bonding wire.

### BRIEF DESCRIPTION OF THE DRAWINGS

FIG. 1 is a plan view of a semiconductor device according to a first embodiment of the present disclosure.

FIG. 2 is a plan view corresponding to FIG. 1, showing the sealing resin in transparency.

FIG. 3 is a right side view of the semiconductor device shown in FIG. 1.

FIG. 4 is a front view of the semiconductor device shown in FIG. 1.

FIG. 5 is a rear view of the semiconductor device shown in FIG. 1.

FIG. 6 is a cross-sectional view along line VI-VI in FIG. 2.

FIG. 7 is a cross-sectional view along line VII-VII in FIG. 2.

FIG. 8 is a cross-sectional view along line VIII-VIII in FIG. 2.

FIG. 9 is an enlarged view of a portion of FIG. 7.

FIG. 10 is a plan view of a semiconductor device according to a variation of the first embodiment of the present disclosure, showing the sealing resin in transparency.

FIG. 11 is a cross-sectional view along line XI-XI in FIG. 10.

FIG. 12 is a plan view of a semiconductor device according to a second embodiment of the present disclosure, showing the sealing resin in transparency.

FIG. 13 is a plan view of a semiconductor device according to a first variation of the second embodiment of the present disclosure, showing the sealing resin in transparency.

FIG. 14 is a plan view of a semiconductor device according to a second variation of the second embodiment of the present disclosure, showing the sealing resin in transparency.

FIG. 15 is a right side view of a semiconductor device according to a third embodiment of the present disclosure.

FIG. 16 is a front view of the semiconductor device shown in FIG. 15.

FIG. 17 is a cross-sectional view of the semiconductor device shown in FIG. 15.

FIG. 18 is a plan view of a semiconductor device according to a fourth embodiment of the present disclosure.

FIG. 19 is a plan view corresponding to FIG. 18, showing the sealing resin in transparency.

FIG. 20 is a right side view of the semiconductor device shown in FIG. 18.

FIG. 21 is a front view of the semiconductor device shown in FIG. 18.

FIG. 22 is a cross-sectional view along line XXII-XXII in FIG. 19.

FIG. 23 is a cross-sectional view along line XXIII-XXIII in FIG. 19.

### DETAILED DESCRIPTION OF EMBODIMENTS

Details of the present disclosure will be explained below referring to the accompanying drawings.

### First Embodiment:

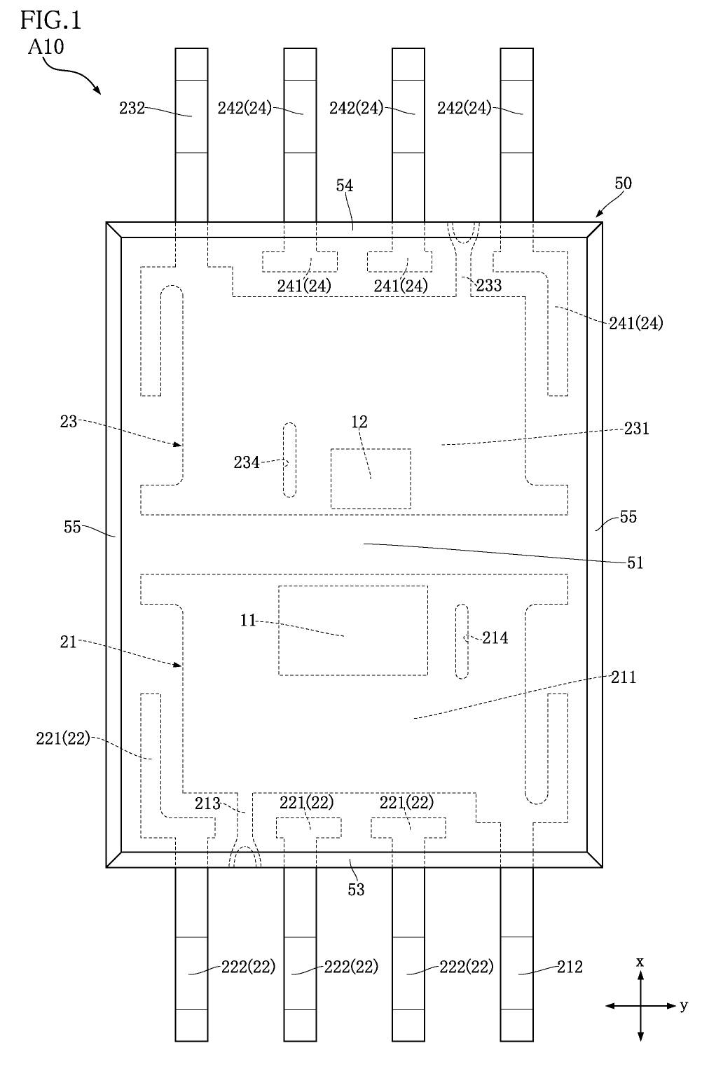

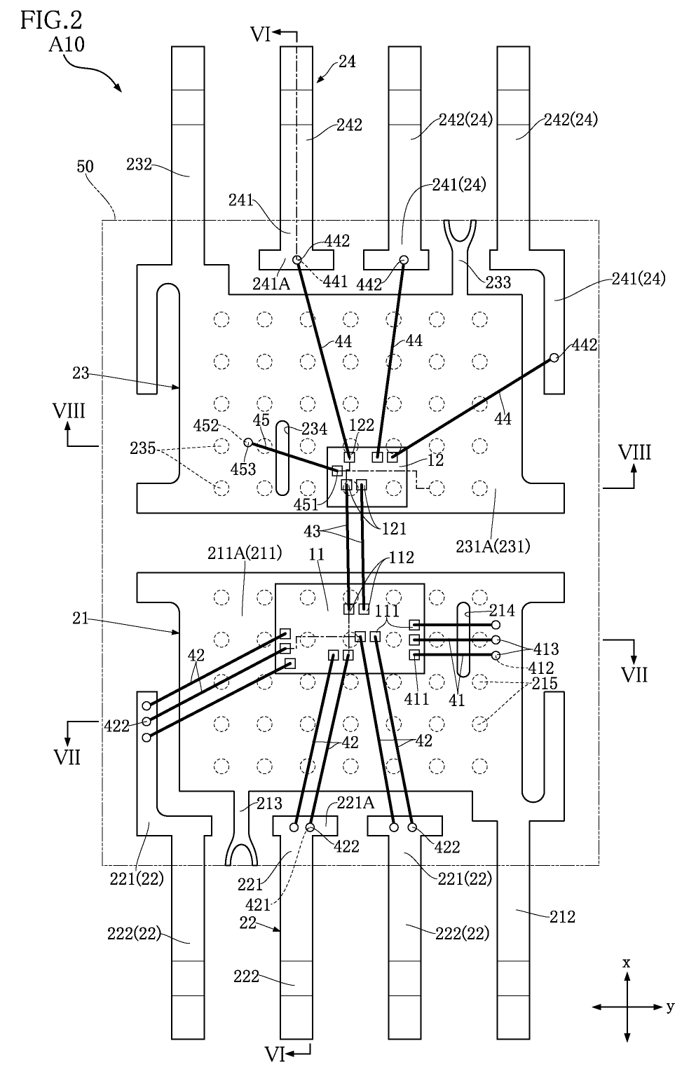

Based on FIGS. 1 to 9,a semiconductor device A10 according to the first embodiment of the present disclosure will be described. The semiconductor device A10 comprises a first semiconductor element 11, a second semiconductor element 12, a first lead 21, a plurality of second leads 22, a third lead 23, a plurality of fourth leads 24, a plurality of first wires 41, a plurality of second wires 42, two third wires 43, a plurality of fourth wires 44, a fifth wire 45, and a sealing resin 50. The semiconductor device A10 may be surface-mounted onto a wiring board of an inverter device in various electrical equipment. The package form of the semiconductor device A10 is SOP (Small Outline Package). The package form of the semiconductor device A10 is not limited to SOP. FIG. 2, for convenience of understanding, shows the sealing resin 50 as transparent. In FIG. 2, the outer contour of the sealing resin 50 is indicated by an imaginary line (two-dot dashed line).

For convenience in describing the semiconductor device A10, the normal direction of the first mount surface 211A of the first pad portion 211 of the first lead 21 is referred to as the “first direction z”. One direction orthogonal to the first direction z is referred to as the “second direction x”. A direction orthogonal to both the first direction z and the second direction x is referred to as the “third direction y”.

The first semiconductor element 11 drives a switching element provided outside the semiconductor device A10. The switching element is, for example, an IGBT (Insulated Gate Bipolar Transistor) or a MOSFET (Metal-Oxide-Semiconductor Field-Effect Transistor). The first semiconductor element 11 comprises a receiving circuit for receiving a PWM (Pulse Width Modulation) control signal, a driving circuit for driving the switching element based on the PWM control signal, and a transmitting circuit for transmitting an electrical signal to the second semiconductor element 12. The electrical signal may be, for example, an output signal from a temperature sensor positioned near a motor.

The second semiconductor element 12 controls the first semiconductor element 11. The second semiconductor element 12 comprises a converting circuit that converts an electrical signal inputted from a device other than the semiconductor device A10 into a PWM control signal, a transmitting circuit for transmitting the PWM control signal to the first semiconductor element 11, and a receiving circuit for receiving an electrical signal from the first semiconductor element 11.

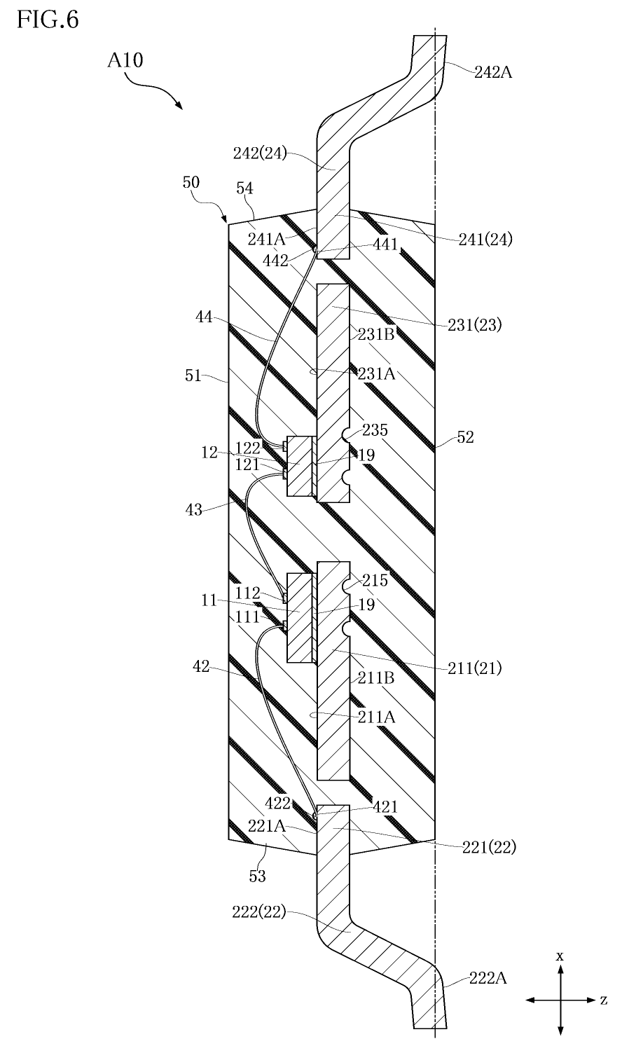

As shown in FIGS. 2 and 6, the first semiconductor element 11 has a plurality of first electrodes 111 and two second electrodes 112. The plurality of first electrodes 111 are conductive to a driving circuit for driving the switching element based on the PWM control signal. One of the two second electrodes 112 is conductive to a receiving circuit that receives the PWM control signal. The other second electrode 112 is conductive to a transmitting circuit for transmitting an electrical signal to the second semiconductor element 12.

As shown in FIGS. 2 and 6, the second semiconductor element 12 has two third electrodes 121 and a plurality of fourth electrodes 122. One of the two third electrodes 121 is conductive to a transmitting circuit for transmitting a PWM control signal to the first semiconductor element 11. The other third electrode 121 is connected to a receiving circuit that receives electrical signals from the first semiconductor element 11. The plurality of fourth electrodes 122 are connected to a converting circuit that converts electrical signals inputted from a device other than the semiconductor device A10 into PWM control signals.

The sealing resin 50, as shown in FIG. 1, covers the first semiconductor element 11 and the second semiconductor element 12, and also covers a part of each lead (the first lead 21, the plurality of second leads 22, the third lead 23, and the plurality of fourth leads 24). As shown in FIGS. 6 to 8, the sealing resin 50 further covers the first wires 41, the second wires 42, the two third wires 43, the fourth wires 44, and the fifth wire 45. The sealing resin 50 is an insulator. The sealing resin 50 is made of a material including, for example, an epoxy resin. As viewed in the first direction z, the sealing resin 50 is rectangular.

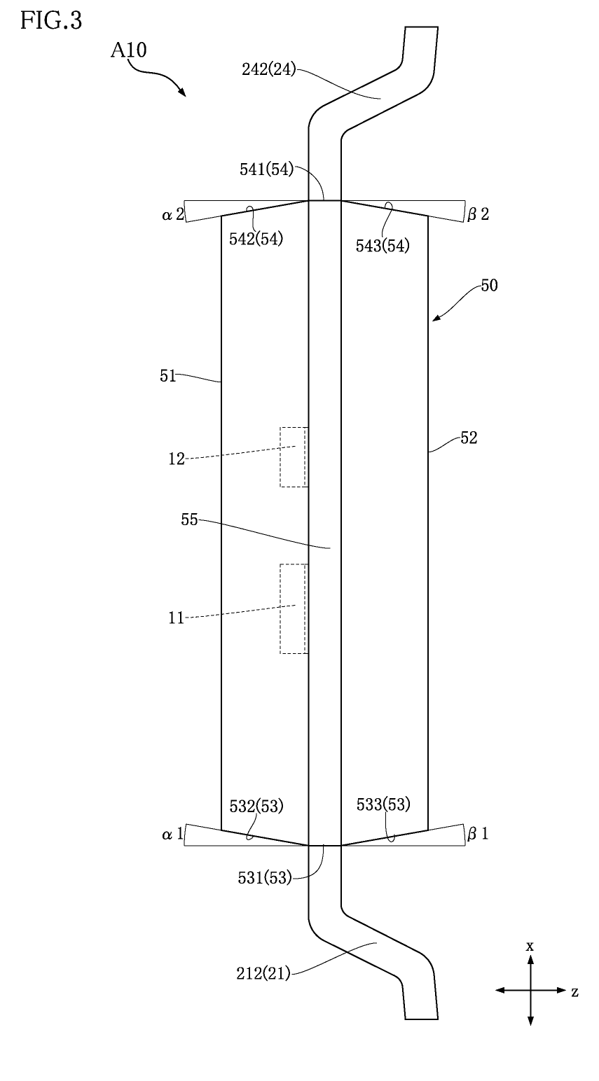

As shown in FIGS. 3 to 5, the sealing resin 50 has a top surface 51, a bottom surface 52, a first side surface 53, a second side surface 54, and two third side surfaces 55.

As shown in FIGS. 3 to 5, the top surface 51 and bottom surface 52 face away from each other in the first direction z. The top surface 51 faces the same side as the first mount surface 211A of the first pad portion 211 of the first lead 21 in the first direction z.

As shown in FIG. 3, the first side surface 53 connects to the top surface 51 and bottom surface 52 and faces one side in the second direction x. The first side surface 53 is positioned closer to the first lead 21 than is the second side surface 54. The first side surface 53 includes a first region 531, a second region 532, and a third region 533. The first region 531 includes the first direction z as an in-plane direction. As viewed in the first direction z, the first region 531 is positioned outwardly relative to both the top surface 51 and the bottom surface 52. The second region 532 is positioned between the first region 531 and the top surface 51 in the first direction z. The third region 533 is positioned on the opposite side with respect to the first region 531 from the second region 532. Each of the second region 532 and the third region 533 is inclined relative to the first region 531. The inclination angle α1 of the second region 532 relative to the first region 531 is equal to the inclination angle β1 of the third region 533 relative to the first region 531.

As shown in FIG. 3, the second side surface 54 connects to the top surface 51 and bottom surface 52, and faces away from the first side surface 53 in the second direction x. The second side surface 54 is positioned closer to the third lead 23 than is the first side surface 53. The second side surface 54 includes a fourth region 541, a fifth region 542, and a sixth region 543. The fourth region 541 includes the first direction z as an in-plane direction. As viewed in the first direction z, the fourth region 541 is positioned outwardly relative to both the top surface 51 and the bottom surface 52. The fifth region 542 is positioned between the fourth region 541 and the top surface 51 in the first direction z. The sixth region 543 is positioned on the opposite side from the fifth region 542 with respect to the fourth region 541. Each of the fifth region 542 and sixth region 543 is inclined relative to the fourth region 541. The inclination angle α2 of the fifth region 542 relative to the fourth region 541 is equal to the inclination angle β2 of the sixth region 543 relative to the fourth region 541.

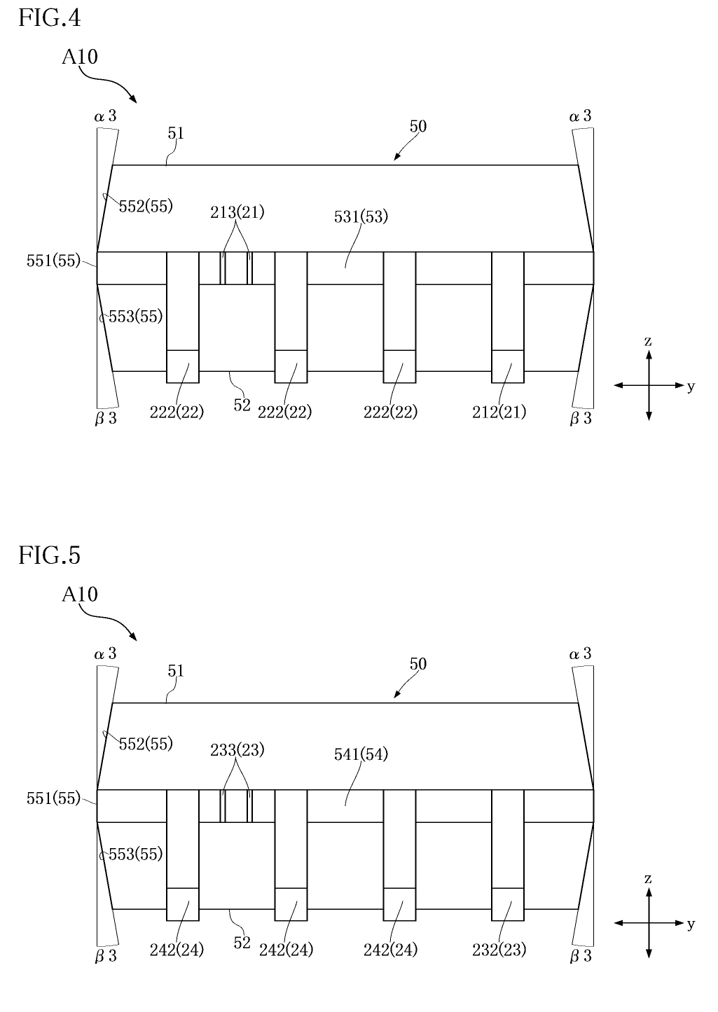

As shown in FIGS. 4 and 5, the two third side surfaces 55 connect to the top surface 51 and bottom surface 52, respectively, and face away from each other in the third direction y. The two third side surfaces 555 each include a seventh region 551, an eighth region 552, and a ninth region 553. The seventh region 551 includes the first direction z as an in-plane direction. As viewed in the first direction z, the seventh region 551 is positioned outward relative to the top surface 51 and bottom surface 52. The eighth region 552 is positioned between the seventh region 551 and the top surface 51 in the first direction z. The ninth region 553 is positioned on the opposite side from the eighth region 552 with respect to the seventh region 551. The eighth region 552 and the ninth region 553 are inclined relative to the seventh region 551. The inclination angle α3 of the eighth region 552 relative to the seventh region 551 is equal to the inclination angle β3 of the ninth region 553 relative to the seventh region 551.

The first lead 21, the plurality of second leads 22, the third lead 23, and the plurality of fourth leads 24 may all contain copper (Cu). These leads are obtained by processing the same lead frame.

The first lead 21 is positioned to one side of the third lead 23 in the second direction x, as shown in FIGS. 1 and 2. The first lead 21 is conductively connected to at least one of the plurality of first electrodes 111 of the first semiconductor element 11. The first lead 21 includes a first pad portion 211, a first terminal portion 212, and a first support portion 213.

As shown in FIGS. 2, 6, and 7, the first pad portion 211 mounts the first semiconductor element 11. The first pad portion 211 has a first mount surface 211A and a first back surface 211B that face away from each other in the first direction z. The first mount surface 211A faces the same side as the top surface 51 of the sealing resin 50 in the first direction z. The first semiconductor element 11 is bonded to the first mount surface 211A via a bonding layer 19. The bonding layer 19 may be made of a paste containing metal particles. The metal particles are, for example, silver (Ag), whereby the bonding layer 19 is a conductor. Alternatively, the bonding layer 19 may be solder.

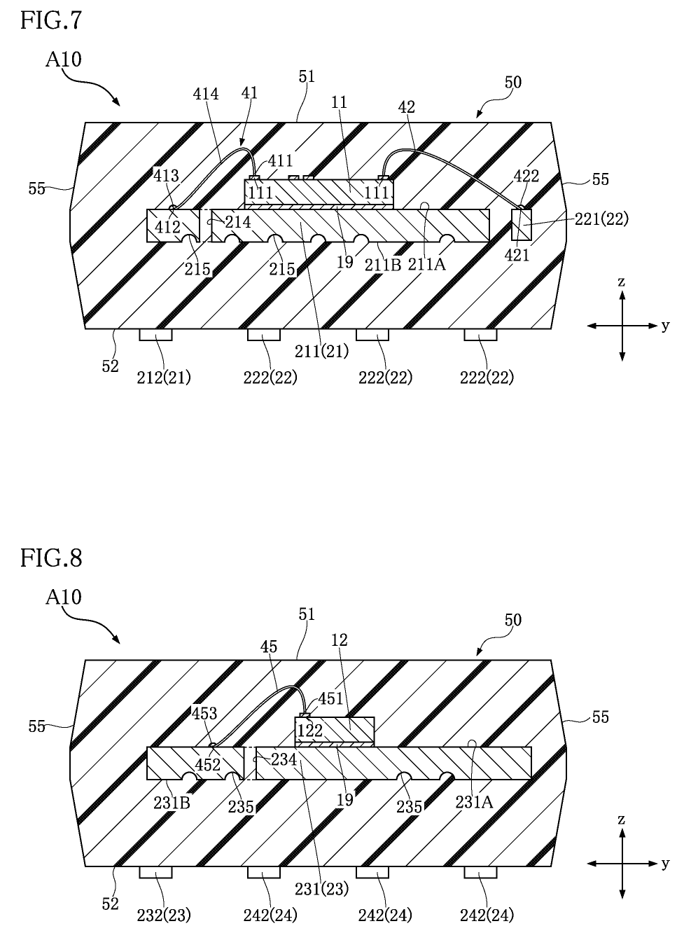

As shown in FIGS. 2 and 7, the first pad portion 211 is formed with a first hole 214 extending from the first mount surface 211A to penetrate through the first pad portion 211. As shown in FIG. 2, the first hole 214 is elongated in the second direction x. A portion of the sealing resin 50 is accommodated in the first hole 214.

As shown in FIGS. 6 and 7, the first pad portion 211 is formed with a plurality of first recesses 215 recessed from the first back surface 211B. Referring to FIG. 2, as viewed in the first direction z, the plurality of first recesses 215 may be arranged in a grid pattern. A portion of the sealing resin 50 is accommodated in each of the first recesses 215.

As shown in FIGS. 1 and 2, the first terminal portion 212 is connected to the first pad portion 211 on one side in the second direction x. As shown in FIG. 4, the first terminal portion 212 protrudes outward from the first region 531 of the first side surface 53 of the sealing resin 50. As viewed in the first direction z, the first terminal portion 212 extends in the second direction x. Referring to FIG. 3, as viewed in the third direction y, the first terminal portion 212 is bent in a gull-wing shape. The surface of the first terminal portion 212 may be plated, for example, with tin.

As shown in FIGS. 1 and 2, the first support portion 213 is positioned on the same side as the first terminal portion 212 relative to the first pad portion 211 in the second direction x. The first support portion 213 is connected to the first pad portion 211. As shown in FIG. 4, the first support portion 213 is exposed from the first region 531 of the first side surface 53 of the sealing resin 50.

As shown in FIGS. 1 and 2, the plurality of second leads 22 are positioned opposite from the third lead 23 with respect to the first semiconductor element 11 in the second direction x. The plurality of second leads 22 are arranged side by side along the third direction y. Each of the plural second leads 22 is electrically connected to at least one of the plural first electrodes 111 of the first semiconductor element 11.

As shown in FIGS. 2 and 6, each of the plurality of second leads 22 includes a first inner portion 221 and a first outer portion 222. The first inner portion 221 is covered by the sealing resin 50. As shown in FIG. 6, the first inner portion 221 has a first connecting surface 221A. The first connecting surface 221A faces the same side as the first mount surface 211A of the first pad portion 211 of the first lead 21 in the first direction z. The first connecting surface 221A and the first mount surface 211A are each contained within the same plane. The first outer portion 222 is connected to the first inner portion 221. As shown in FIG. 4, the first outer portion 222 protrudes from the first region 531 of the first side surface 53 of the sealing resin 50. As viewed in the first direction z, the first outer portion 222 extends in the second direction x. As viewed in the third direction y, the first outer portion 222 is curved or bent in a gull-wing shape. The shape of the first outer portion 222 is identical to the shape of the portion of the first terminal portion 212 (see FIG. 3) of the first lead 21 protruding from the sealing resin 50. The surface of the first outer portion 222 may be plated, for example, with tin.

As shown in FIG. 6, the first outer portion 222 has a first mounting surface 222A. The first mounting surface 222A faces away from the first connecting surface 221A of the first inner portion 221 in the first direction z. The first mounting surface 222A is located farthest from the first connecting surface 221A in the first direction z. The first mounting surface 222A protrudes beyond a virtual plane containing the bottom surface 52 of the sealing resin 50. The first mounting surface 222A is inclined relative to the bottom surface 52.

The third lead 23 is positioned opposite from the second leads 22 with respect to the first semiconductor element 11 in the second direction x, as shown in FIGS. 1 and 2. The third lead 23 is electrically connected to one of the fourth electrodes 122 of the second semiconductor element 12. The third lead 23 includes a second pad portion 231, a second terminal portion 232, and a second support portion 233.

As shown in FIGS. 2, 6, and 8, the second pad portion 231 mounts the second semiconductor element 12. The second pad portion 231 has a second mount surface 231A and a second back surface 231B facing away from each other in the first direction z. The second mount surface 231A faces the same side as the top surface 51 of the sealing resin 50 in the first direction z. The second semiconductor element 12 is bonded to the second mount surface 231A via a bonding layer 19.

As shown in FIGS. 2 and 8, a second hole 234 is formed in the second pad portion 231, extending through the second pad portion 231 from the second mount surface 231A. The second hole 234 extends (is elongated) in the second direction x. A portion of the sealing resin 50 is accommodated in the second hole 234.

As shown in FIGS. 6 and 8, the second pad portion 231 is formed with a plurality of second recesses 235 recessed from the second back surface 231B. Referring to FIG. 2, as viewed in the first direction z, the plurality of second recesses 235 are arranged in a grid pattern. A portion of the sealing resin 50 is accommodated in each of the second recesses 235.

As shown in FIGS. 1 and 2, the second terminal portion 232 is positioned opposite from the first lead 21 with respect to the second pad portion 231 in the second direction x. The second terminal portion 232 is connected to the second pad portion 231. As shown in FIG. 5, the second terminal portion 232 protrudes from the fourth region 541 of the second side surface 54 of the sealing resin 50. As viewed in the first direction z, the second terminal portion 232 extends in the second direction x. As viewed in the third direction y, the second terminal portion 232 is bent in a gull-wing shape. The shape of the second terminal portion 232 is identical to the shape of the second outer portion 242 (see FIG. 3) of one of the fourth leads 24. The surface of the second terminal portion 232 may be plated, for example, with tin.

As shown in FIGS. 1 and 2, the second support portion 233 is positioned on the same side as the second terminal portion 232 relative to the second pad portion 231 in the second direction x. The second support portion 233 is connected to the second pad portion 231. As shown in FIG. 5, the second support portion 233 is exposed from the fourth region 541 of the second side surface 54 of the sealing resin 50.

The plurality of fourth leads 24 are positioned opposite from the first lead 21 with respect to the second semiconductor element 12 in the second direction x, as shown in FIGS. 1 and 2. The plurality of fourth leads 24 are arranged side by side along the third direction y. Each of the plurality of fourth leads 24 is conductively connected to at least one of the plurality of fourth electrodes 122 of the second semiconductor element 12.

As shown in FIGS. 2 and 6, each of the plurality of fourth leads 24 includes a second inner portion 241 and a second outer portion 242. The second inner portion 241 is covered by the sealing resin 50. As shown in FIG. 6, the second inner portion 241 has a second connecting surface 241A. The second connecting surface 241A faces the same side as the second mount surface 231A of the second pad portion 231 of the third lead 23 in the first direction z. The second connecting surface 241A and the second mount surface 231A are each contained within the same plane. The second outer portion 242 is connected to the second inner portion 241. As shown in FIG. 5, the second outer portion 242 protrudes outward from the fourth region 541 of the second side surface 54 of the sealing resin 50. As viewed in the first direction z, the second outer portion 242 extends in the second direction x. Referring to FIG. 3, as viewed in the third direction y, the second outer portion 242 is curved or bent in a gull-wing shape. The surface of the second outer portion 242 may be plated, for example, with tin.

As shown in FIG. 6, the second outer portion 242 has a second mounting surface 242A. The second mounting surface 242A faces away from the second connecting surface 241A of the second inner portion 241 in the first direction z. The second mounting surface 242A is located furthest from the second connecting surface 241A in the first direction z. In the first direction z, the second mounting surface 242A protrudes from the virtual plane including the bottom surface 52 of the sealing resin 50 (in other words, the second mounting surface 242A is located opposite from the second connecting surface 241A with respect to the virtual plane). The second mounting surface 242A is inclined relative to the bottom surface 52.

Each of the plurality of first wires 41 is conductively bonded, as shown in FIG. 2, to one of the plurality of first electrodes 111 of the first semiconductor element 11 and to the first mount surface 211A of the first pad portion 211 of the first lead 21. This enables the first lead 21 to conduct to the first semiconductor element 11. The plurality of first wires 41 provide the ground of the first semiconductor element 11. As shown in FIG. 7, each of the plurality of first wires 41 has a first bonding portion 411, a second bonding portion 412, and a main portion 414. The first bonding portion 411 is conductively bonded to one of the plurality of first electrodes 111. The second bonding portion 412 is conductively bonded to the first mounting surface 211A. As viewed in the first direction z, the second bonding portion 412 of each first wire 41 is spaced apart from the first recesses 215 provided in the first pad portion 211A. The main portion 414 is positioned or extends between the first bonding portion 411 and the second bonding portion 412.

As shown in FIGS. 2 and 7, the first hole 214 provided in the first pad portion 211 of the first lead 21 is positioned closer to the second bonding portions 412 of the plurality of first wires 41 than to the first bonding portions 411 of the plurality of first wires 41. In the semiconductor device A10, as viewed in the first direction z, the plurality of first wires 41 overlap with the first hole 214. As viewed in the first direction z, the plurality of first wires 41 each extend in the third direction y. As viewed in the first direction z, the first hole 214 extends or is elongated in a direction orthogonal to the direction in which each first wire 41 extends.

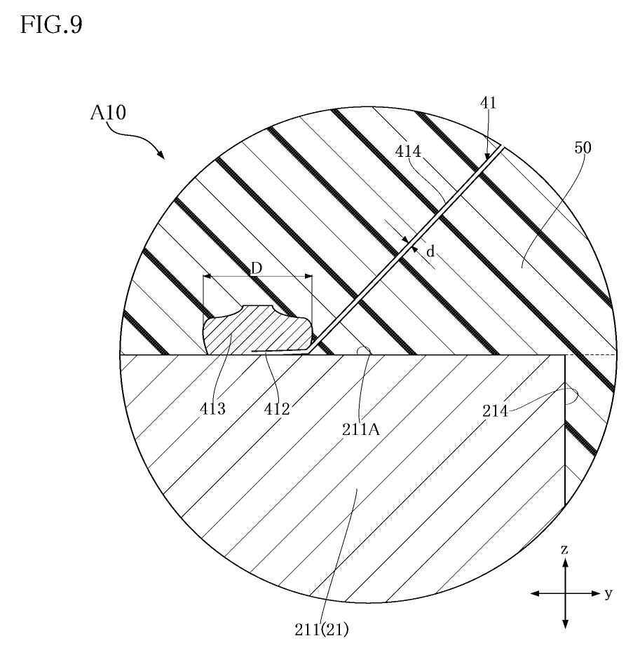

As shown in FIGS. 2 and 7, each first wire 41 is provided with a first protrusion 413. The first protrusion 413 corresponds to a ball bonding portion formed by wire bonding. The first protrusion 413 overlaps or is disposed on the second bonding portion 412 of the first wire 41, while also being covered by the sealing resin 50. As shown in FIG. 9, each first protrusion 413 contacts the corresponding second bonding portion 412 and the first mount surface 211A of the first pad portion 211 as well. The dimension D of the first protrusion 413 in a direction orthogonal to the first direction z is larger than the dimension d of the main portion 414 in a direction orthogonal to the direction in which the first wire 41 extends. Further, the dimension D of the first protrusion 413 is larger than the dimension of the second bonding portion 412 in the direction perpendicular to the first direction z.

Each of the second wires 42 is conductively bonded, as shown in FIG. 2, to one of the plural first electrodes 111 of the first semiconductor element 11 and to the first inner portion 221 of one of the second leads 22. This enables the second leads 22 to conduct electricity to the first semiconductor element 11. As shown in FIG. 6, each second wire 42 has a third bonding portion 421. The third bonding portion 421 is conductively bonded to the first connecting surface 221A of the first inner portion 221 of the second lead 22.

As shown in FIGS. 2 and 6, a second protrusion 422 is provided on each second wire 42. The second protrusion 422 corresponds to a ball bonding portion formed by wire bonding. The second protrusion 422 overlaps the third bonding portion 421 of the second wire 42, while also being covered by the sealing resin 50.

The two third wires 43 are conductively bonded, respectively, to the two second electrodes 112 of the first semiconductor element 11 and the two third electrodes 121 of the second semiconductor element 12, as shown in FIGS. 2 and 6. This enables the first semiconductor element 11 and the second semiconductor element 12 to conduct electricity to each other. As viewed in the first direction z, the two third wires 43 span or extend to cross the gap between the first pad portion 211 of the first lead 21 and the second pad portion 231 of the third lead 23.

As shown in FIG. 2, each fourth wire 44 is conductively bonded to one of the plurality of fourth electrodes 122 of the second semiconductor element 12 and to the second inner portion 241 of one of the plurality of fourth leads 24. This enables the plurality of fourth leads 24 to conduct electricity to the second semiconductor element 12. As shown in FIG. 6, each fourth wire 44 has a fourth bonding portion 441. The fourth bonding portion 441 is conductively bonded to the second connecting surface 241A of the second inner portion 241 of the corresponding fourth lead 24.

As shown in FIGS. 2 and 6, each fourth wire 44 is provided with a third protrusion 442. The third protrusion 442 corresponds to a ball bonding portion formed by wire bonding. The third protrusion 442 overlaps the fourth bonding portion 441 of the fourth wire 44 while also being covered by the sealing resin 50.

As shown in FIG. 2, the fifth wire 45 is conductively bonded to one of the plurality of fourth electrodes 122 of the second semiconductor element 12 and to the second mount surface 231A of the second pad portion 231 of the third lead 23. This enables the third lead 23 to conduct to the second semiconductor element 12. The fifth wire 45 provides the ground for the second semiconductor element 12. As shown in FIG. 8, the fifth wire 45 has a fifth bonding portion 451 and a sixth bonding portion 452. The fifth bonding portion 451 is conductively bonded to the fourth electrode 122. The sixth bonding portion 452 is conductively bonded to the second mount surface 231A. As viewed in the first direction z, the sixth bonding portion 452 is spaced apart from the second recesses 235 provided in the second pad portion 231.

As shown in FIGS. 2 and 8, the second hole 234 provided in the second pad portion 231 of the third lead 23 is positioned closer to the sixth bonding portion 452 than to the fifth bonding portion 451. As viewed in the first direction z, the fifth wire 45 overlaps the second hole 234. As viewed in the first direction z, the fifth wire 45 extends substantially along the third direction y. As viewed in the first direction z, the second hole 234 extends in a direction perpendicular (or generally perpendicular) to the direction in which the fifth wire 45 extends. In other words, the second hole and the fifth wire 45 cross each other.

As shown in FIGS. 2 and 8, the fifth wire 45 is provided with a fourth protrusion 453. The fourth protrusion 453 corresponds to a ball bonding portion formed by wire bonding. The fourth protrusion 453 overlaps the sixth bonding portion 452 while also being covered by the sealing resin 50.

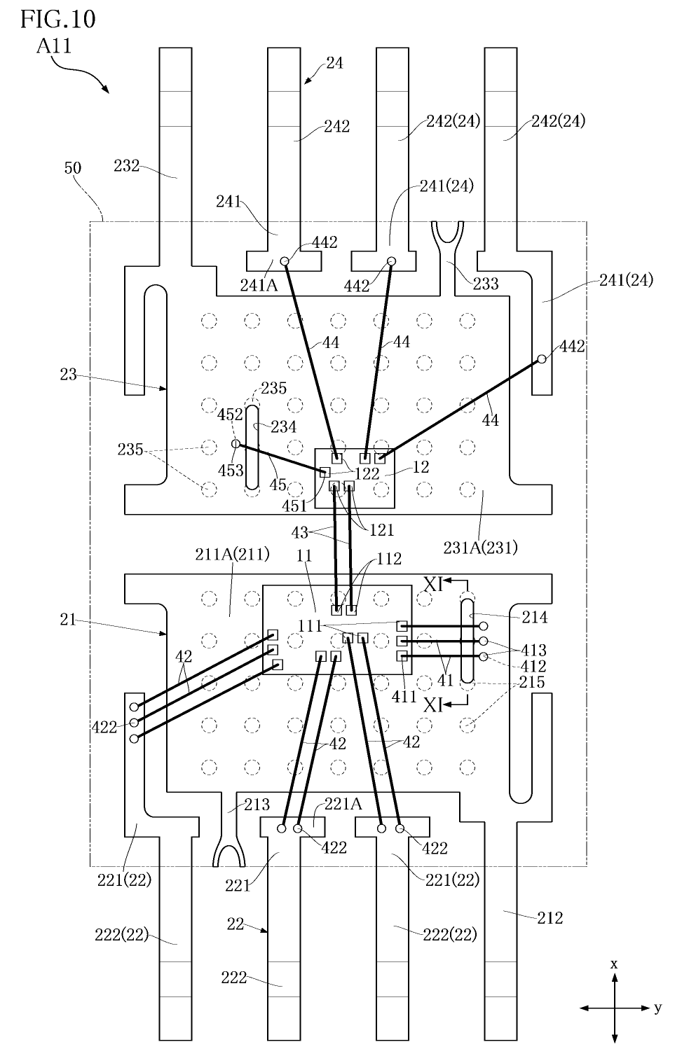

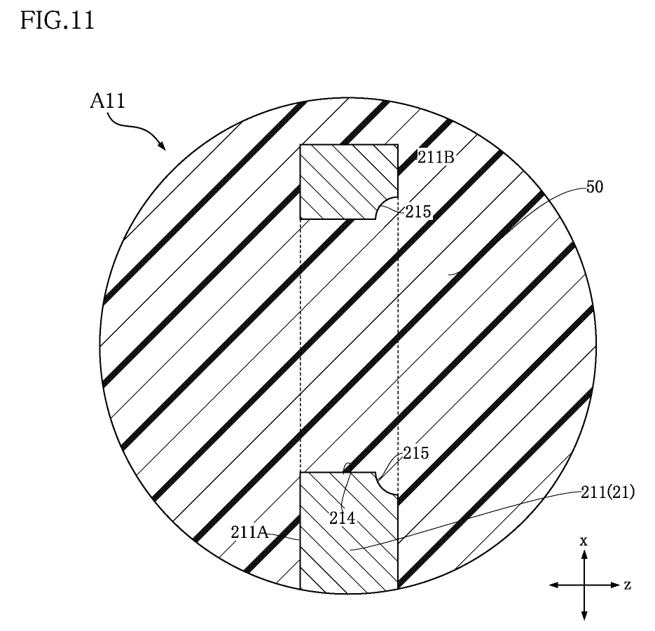

Next, referring to FIGS. 10 and 11, a semiconductor device A11 as a variation of the semiconductor device A10 will be described. FIG. 10, for convenience of understanding, shows the sealing resin 50 as transparent. In FIG. 10, the outer shape of the sealing resin 50 is shown by an imaginary line.

The semiconductor device A11 may differ from the semiconductor device A10 in the configuration of the first hole 214 in the first pad portion 211 and the second hole 234 in the second pad portion 231. As shown in FIGS. 10 and 11, the first hole 214 is connected to (or continuous with) one or more of the plurality of first recesses 215 in the first pad portion 211. Likewise, the second hole 234 is connected to at least one of the second recesses 235 in the second pad portion 231.

Next, some of the advantages of the semiconductor device A10 will be described.

The semiconductor device A10 comprises a first lead 21 including a first pad portion 211, a first semiconductor element 11, a first wire(s) 41, and a sealing resin 50. The first wire 41 has a first bonding portion 411 and a second bonding portion 412. A first protrusion 413 is provided on the first wire 41. The first protrusion 413 overlaps the second bonding portion 412 while being covered by the sealing resin 50. A first hole 214 is provided in the first pad portion 211. The first hole 214 is positioned closer to the second bonding portion 412 than to the first bonding portion 411. The first hole 214 extends vertically from the first mount surface 211A of the first pad portion 211 and penetrates through the first pad portion 211 in the first direction z. A portion of the sealing resin 50 is accommodated or fitted within the first hole 214. With such a configuration, the first protrusion 413 may prevent the second bonding portion 412 from peeling away from the first mount surface 211A. Furthermore, the sealing resin 50 includes a portion that covers the first protrusion 413, and this portion of the sealing resin 50 is close to the other portion of the sealing resin 50 accommodated in the first hole 214. With such a configuration, the sealing resin portion in the first hole 214 can serve to preventing the second bonding portion 412 from peeling off the first mount surface 211A. Thus, with the semiconductor device A10, it is possible to suppress detachment of the first wire 41 from the first pad portion 211.

Each first protrusion 413 is in contact with both the second bonding portion 412 of the first wire 41 and the first mount surface 211A of the first pad portion 211. With such a configuration, detachment of the second bonding portion 412 from the first mount surface 211A can be more effectively prevented.

As viewed in the first direction z, the first wire 41 overlaps with the first hole 214. With such a configuration, the portion of the sealing resin 50 covering the first wire 41 is directly connected (continuous) to the other portion of the sealing resin 50 accommodated in the first hole 214. This allows the second bonding portion 412 (i.e., a part of the first wire 41) to be more effectively prevented from peeling away from the first mount surface 211A.

The first pad portion 211 is provided with first recesses 215 recessed from the first back surface 211B. Portions of the sealing resin 50 are accommodated in the respective first recesses 215. With such a configuration, an anchoring effect is exerted on the sealing resin 50 with respect to the first pad portion 211. This can suppress detachment of the sealing resin 50 from the first pad portion 211.

In the semiconductor device A11 described above, one or more of the first recesses 215 are connected to or integral with the first hole 214. With such a configuration, an anchoring effect may work more effectively for the sealing resin 50 accommodated in the first hole 214 due to such recesses. Hence, it is possible to more effectively prevent the second bonding portion 412 from peeling away from the first mount surface 211A.

As viewed in the first direction z, the second bonding portion 412 of each first wire 41 is spaced apart from the first recesses 215. With such a configuration, it is possible to suppress a decrease in the bonding strength of the second bonding portion 412 with respect to the first mount surface 211A of the first pad portion 211. With such a configuration, it can suppress a decrease in the bonding strength of the second bonding portion 412 with the first mount surface 211A of the first pad portion 211.

Further, by providing the first hole 214 in the first pad portion 211, it is possible to increase the density of the part of the sealing resin 50 to be formed on and above the first mount surface 211A of the first pad portion 211 during the formation of the sealing resin 50 for manufacturing the semiconductor device A10.

The semiconductor device A10 further comprises second leads 22 and second wires 42. Each second wire 42 has a third bonding portion 421 conductively bonded to the second lead 22. A second protrusion 422, covered by sealing resin 50, is provided on the second wire 42 while overlapping the third bonding portion 421. With such a configuration, the second protrusion 422 can prevent the third bonding portion 421 from peeling away from the second lead 22.

### Second Embodiment:

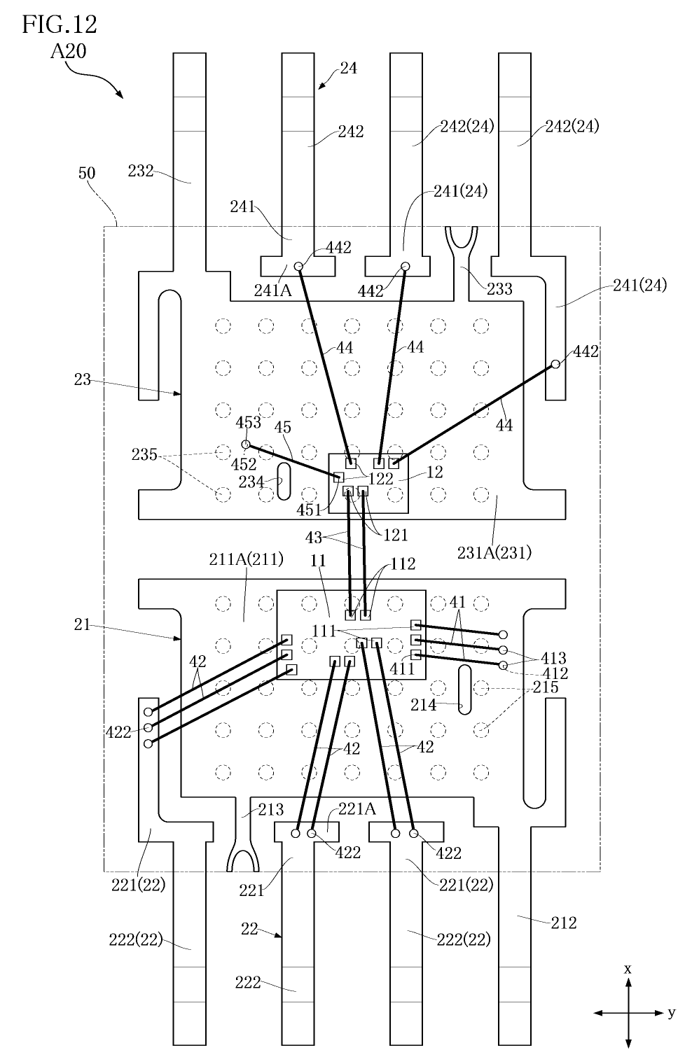

Referring to FIG. 12, the semiconductor device A20 according to a second embodiment of the present disclosure will be described. In this figure, identical or similar elements to those described in the preceding semiconductor device A10 are designated by the same reference numerals, and redundant descriptions are omitted. FIG. 12 shows the sealing resin 50 as transparent for ease of understanding. In FIG. 12, the outer shape of the sealing resin 50 is indicated by an imaginary line.

The semiconductor device A20 may differ from the semiconductor device A10 in the configuration of the first hole 214 provided in the first pad portion 211 of the first lead 21 and the second hole 234 provided in the second pad portion 231 of the third lead 23.

Referring to FIG. 12, as viewed in the first direction z, a plurality of first wires 41 are spaced apart from the first hole 214. In the third direction y, the first hole 214 is positioned between the first bonding portion 411 and the second bonding portion 412 of each first wire 41.

As viewed in the first direction z, the fifth wire 45 is spaced apart from the second hole 234. In the third direction y, the second hole 234 is positioned between the fifth bonding portion 451 and the sixth bonding portion 452 of the fifth wire 45.

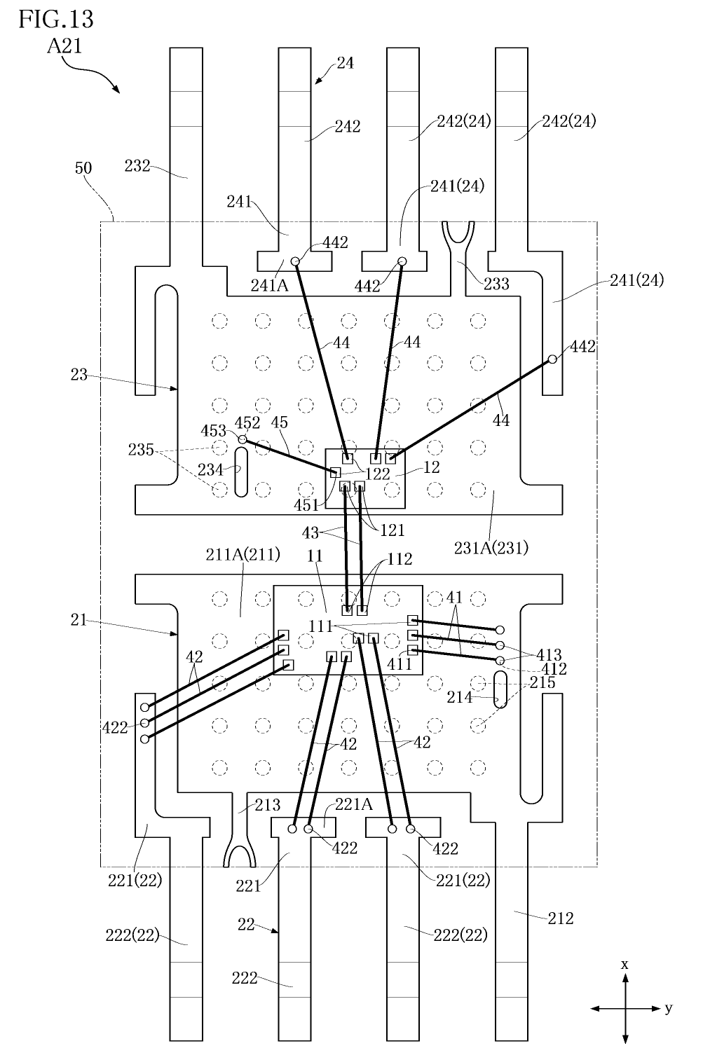

Next, referring to FIG. 13, a semiconductor device A21 is described as a first variation of the semiconductor device A20. FIG. 13 shows the sealing resin 50 as transparent for ease of understanding. In FIG. 13, the outer shape of the sealing resin 50 is indicated by an imaginary line.

The semiconductor device A21 may differ from the semiconductor device A20 in the configuration of the first hole 214 provided in the first pad portion 211 of the first lead 21 and the second hole 234 provided in the second pad portion 231 of the third lead 23. As viewed in the first direction z, the first hole 214 is positioned to one side of the group of second bonding portions 412 of the first wires 41 in a direction perpendicular (or generally perpendicular) to the direction in which each first wire 41 extends. Similarly, as viewed in the first direction z, the second hole 234 is positioned to one side of the sixth bonding portion 452 of the fifth wire 45 in a direction perpendicular (or generally perpendicular) to the direction in which the fifth wire 45 extends.

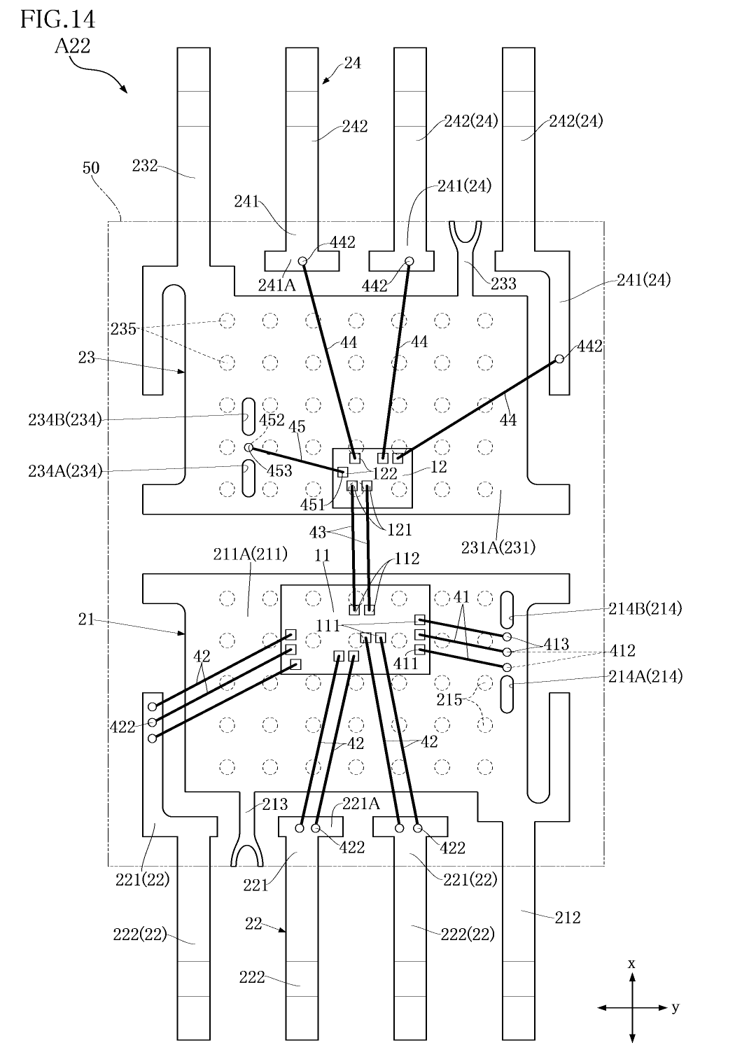

Next, referring to FIG. 14, a semiconductor device A22 is described as a second variation of the semiconductor device A20. FIG. 14, for convenience of understanding, shows the sealing resin 50 as transparent. In FIG. 14, the outer shape of the sealing resin 50 is indicated by an imaginary line.

The semiconductor device A22 may differ from the semiconductor device A20 in the configuration of the first hole 214 provided in the first pad portion 211 of the first lead 21 and the configuration of the second hole 234 provided in the second pad portion 231 of the third lead 23. As shown in FIG. 14, the first hole 214 includes a first part (first sub-hole) 214A and a second part (second sub-hole) 214B spaced apart from each other. As viewed in the first direction z, the first part 214A and the second part 214B are positioned to opposite sides of the group of second bonding portions 412 of the first wires 41 in a direction perpendicular (or generally perpendicular) to the direction in which each first wire 41 extends.

As shown in FIG. 14, the second hole 234 includes a third part (third sub-hole) 234A and a fourth part (fourth sub-hole) 234B spaced apart from each other. As viewed in the first direction z, the third part 234A and the fourth part 234B are positioned to both sides of the sixth bonding portion 452 of the fifth wire 45, respectively, in a direction perpendicular (or generally perpendicular) to the direction in which the fifth wire 45 extends.

Next, some of the advantages of the semiconductor device A20 will be described.

The semiconductor device A20 comprises a first lead 21 including a first pad portion 211, a first semiconductor element 11, first wires 41, and a sealing resin 50. Each first wire 41 has a first bonding portion 411 and a second bonding portion 412. The first wire 41 is provided with a first protrusion 413 that is covered by the sealing resin 50, and that overlaps the second bonding portion 412. The first pad portion 211 is formed with a first hole 214 disposed closer to the second bonding portion 412 than to the first bonding portion 411. The first hole 214 extends vertically from the first mount surface 211A and penetrates through the first pad portion 211 in the first direction z. A portion of the sealing resin 50 is accommodated within the first hole 214. With such a configuration, the semiconductor device A20 can also suppress detachment of the first wire 41 from the first pad portion 211. Furthermore, the semiconductor device A20, provided with configurations common to those of the semiconductor device A10, can enjoy advantages similar to those of the semiconductor device A10.

In the semiconductor device A20, as viewed in the first direction z, the first wires 41 are spaced apart from the first hole 214. In this configuration as well, the portion of sealing resin 50 covering the first protrusions 413 is close to the portion of the sealing resin 50 accommodated in the first hole 214. Thus, in the semiconductor device A20 as well, the peeling of the second bonding portion 412 from the first mount surface 211A can be prevented by the portion of the sealing resin 50 accommodated in the first hole 214.

It should be noted that from the perspective of preventing detachment of the first wires 41 from the first pad portion 211, the relationship between the first hole 214 and the second bonding portions 412 of the first wires 41 may be more favorable in the semiconductor device A21 than in the semiconductor device A20. Furthermore, the semiconductor device A22 may be capable of more effectively suppressing detachment of the first wires 41 from the first pad portion 211 than the semiconductor device A21.

### Third Embodiment:

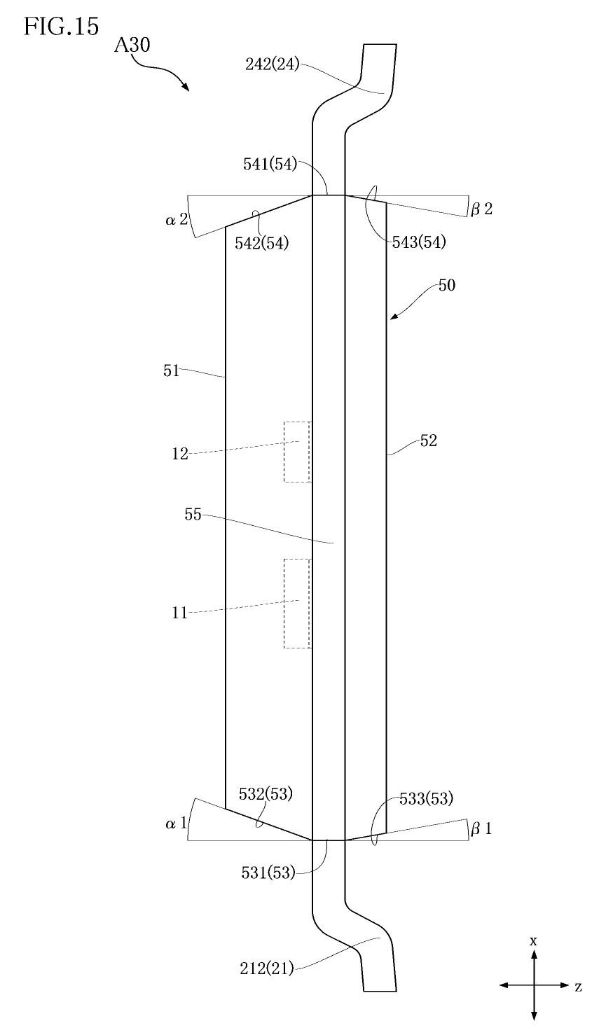

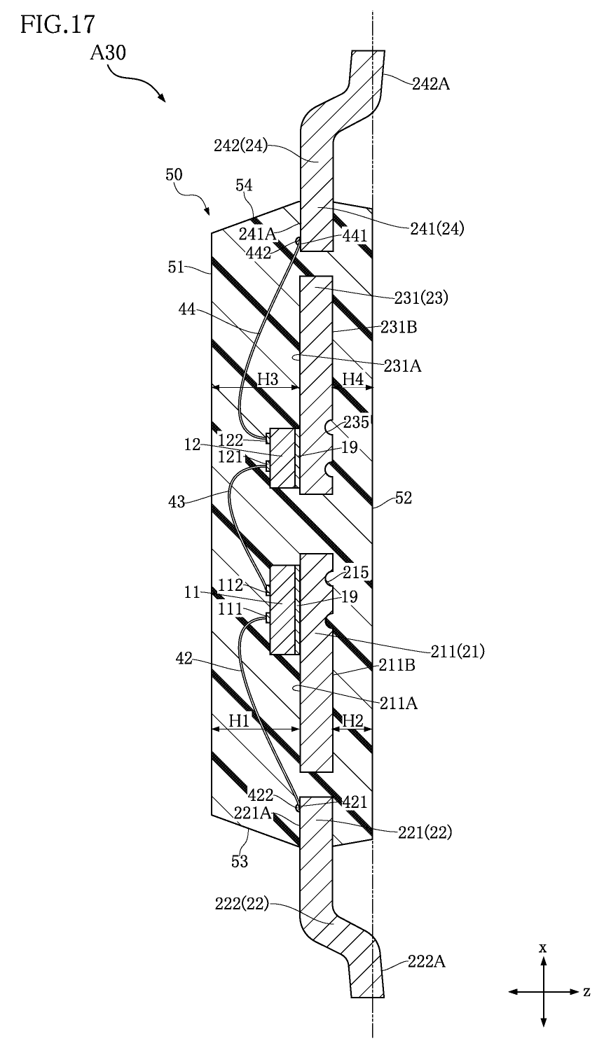

Referring to FIGS. 15 to 17, a semiconductor device A30 according to the third embodiment of the present disclosure is described. In these figures, identical or similar elements to those described above in the semiconductor device A10 are assigned the same reference numerals, and redundant descriptions are omitted. The cross-sectional position in FIG. 17 corresponds to the cross-sectional position in FIG. 6 relating to the semiconductor device A10.

In the semiconductor device A30 may differ from the semiconductor device A10 in the configuration of the sealing resin 50.

As shown in FIG. 17, in the first direction z, the sealing resin 50 has a dimension H1 from the top surface 51 to the first mount surface 211A of the first pad portion 211. Furthermore, the sealing resin 50 has a dimension H2 from the bottom surface 52 to the first back surface 211B of the first pad portion 211 in the first direction z. In the illustrated example, the dimension H1 is larger than the dimension H2. Similarly, in the first direction z, the dimension H3 from the top surface 51 to the second mount surface 231A of the second pad portion 231 is larger than the dimension H4 from the bottom surface 52 to the second back surface 231B of the second pad portion 231.

As shown in FIG. 15, regarding the first side surface 53 of the sealing resin 50, the inclination angle α1 of the second region 532 relative to the first region 531 is greater than the inclination angle β1 of the third region 533 relative to the first region 531. Likewise, regarding the second side surface 54 of the sealing resin 50, the inclination angle α2 of the fifth region 542 relative to the fourth region 541 is greater than the inclination angle β2 of the sixth region 543 relative to the fourth region 541.

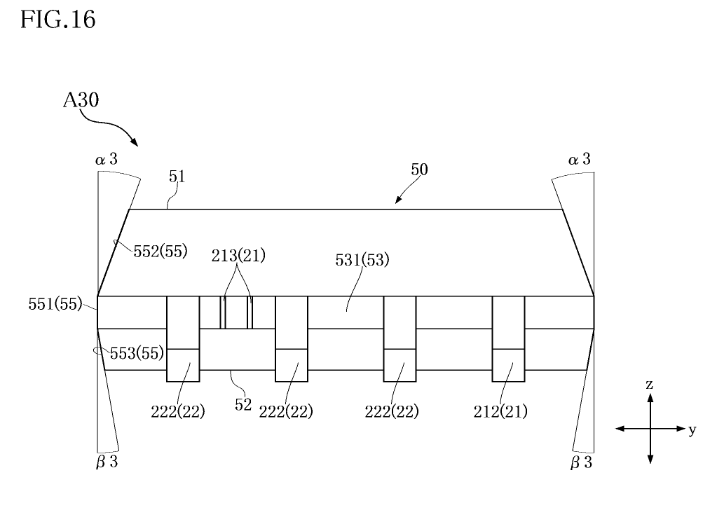

As shown in FIG. 16, regarding the two third side surfaces 55 of the sealing resin 50, the inclination angle α3 of the eighth region 552 relative to the seventh region 551 is greater than the inclination angle β3 of the ninth region 553 relative to the seventh region 551.

Next, some of the advantages of the semiconductor device A30 will be described.

The semiconductor device A30, like the semiconductor device A10, comprises a first lead 21 including a first pad portion 211, a first semiconductor element 11, a plurality of first wires 41, and a sealing resin 50. Each first wire 41 has a first bonding portion 411 and a second bonding portion 412 (see the semiconductor device A10 in FIG. 2). Each first wire 41 is provided with a first protrusion 413 that overlaps the second bonding portion 412 while also being covered by the sealing resin 50. The first pad portion 211 is formed with a first hole 214. The first hole 214 is positioned closer to the second bonding portion 412 than to the first bonding portion 411. The first hole 214 extends vertically from the first mount surface 211A of the first pad portion 211 and penetrates through the first pad portion 211 in the first direction z. A portion of the sealing resin 50 is accommodated in the first hole 214. Thus, in the semiconductor device A30 as well, detachment of the first wire(s) 41 from the first pad portion 211 can be suppressed. Furthermore, the semiconductor device A30 can enjoy the same advantages as the semiconductor device A10 by having a configuration common to that of the semiconductor device A10.

In the semiconductor device A30, the dimension H1 in the first direction z from the top surface 51 of the sealing resin 50 to the first mount surface 211A of the first pad portion 211 is greater than the dimension H2 in the first direction z from the bottom surface 52 of sealing resin 50 to the first back surface 211B of the first pad portion 211. In other words, it is possible to render the dimension H2 small. With such a configuration, while maintaining the desired (great) dimension in the first direction z of the portion of the sealing resin 50 that covers the first wires 41, etc., it is possible to reduce the overall dimension in the first direction z of the semiconductor device A30. This enables a size reduction of the semiconductor device A30, while having the desired insulation withstand voltage ensured.

As shown in FIG. 15, the inclination angle α1 of the second region 532 relative to the first region 531 on the first side surface 53 of the sealing resin 50 is greater than the inclination angle β1 of the third region 533 relative to the first region 531 (similarly, α2 > β2). With such a configuration, when molding is performed to form the resin portion of the sealing resin 50 from the top surface 51 to the first mount surface 211A of the first pad portion 211 in the first direction z, it is possible to suppress the occurrence of defects in the resulting resin portion in separating the mold from the molded resin portion.

### Fourth Embodiment:

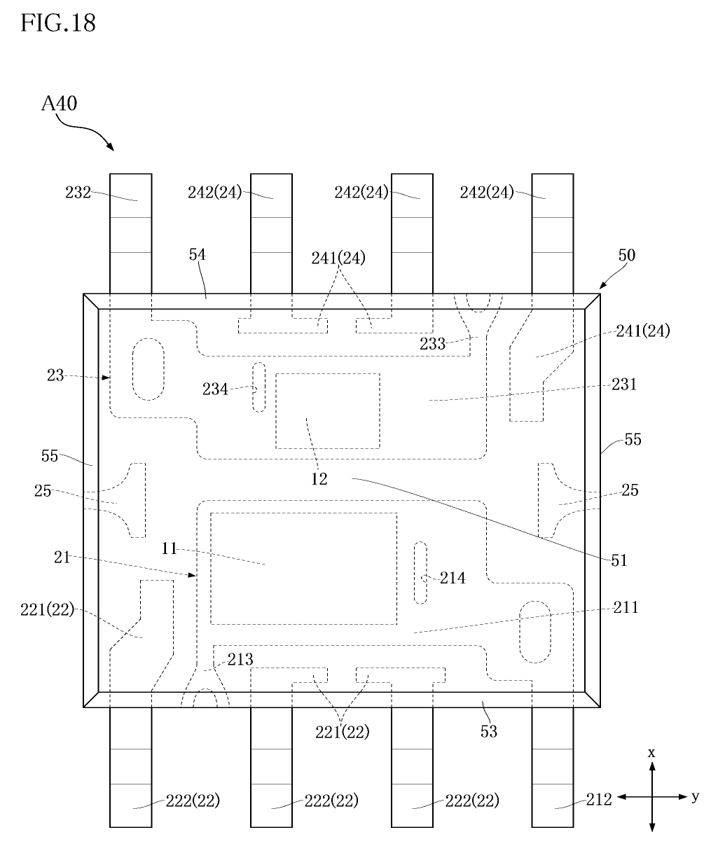

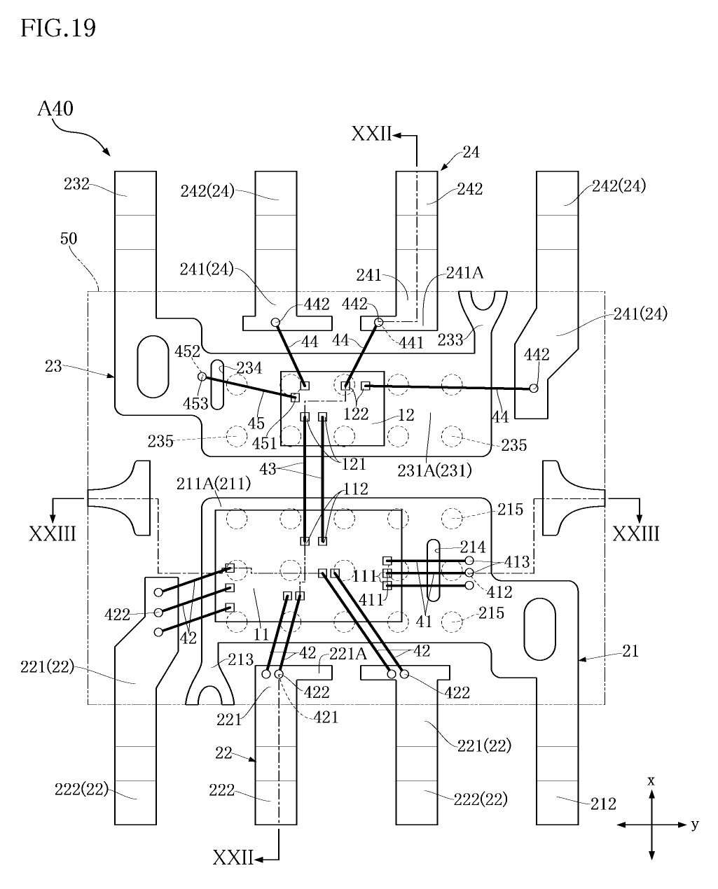

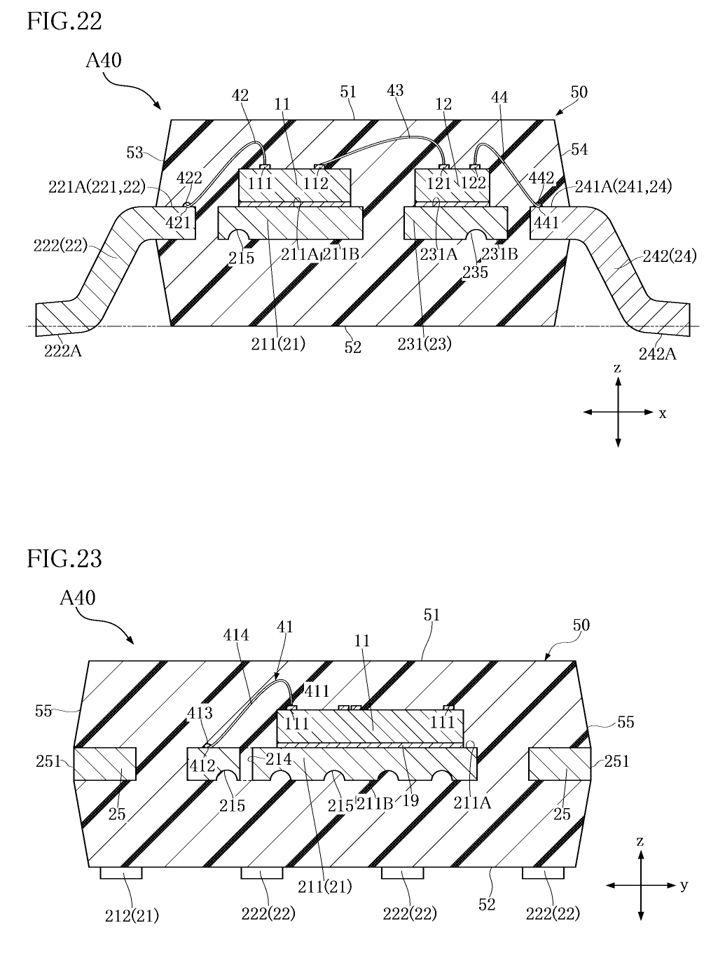

Referring to FIGS. 18 to 23, a semiconductor device A40 according to the fourth embodiment of the present disclosure is described. In these figures, identical or similar elements to those described in the semiconductor device A10 are labeled with the same reference numerals and redundant descriptions are omitted. FIG. 19, for convenience of understanding, shows the sealing resin 50 as transparent. In FIG. 19, the outer contour of the sealing resin 50 is indicated by an imaginary line.

The semiconductor device A40 may differ from the semiconductor device A10 in that it further includes two fifth leads 25.

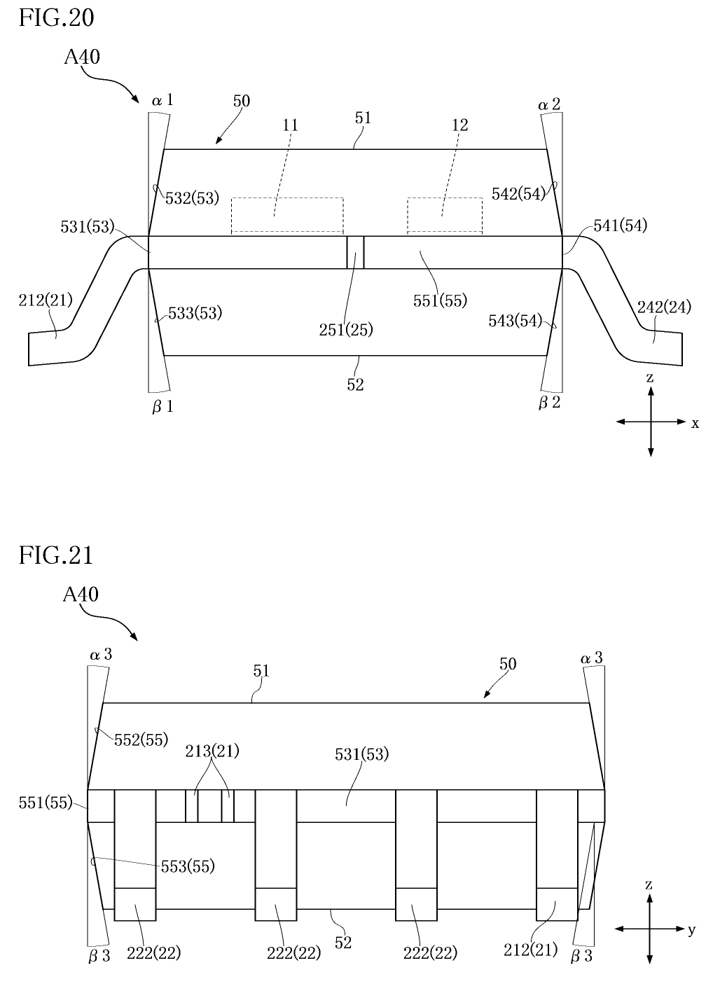

The two fifth leads 25 are located apart from each other in the third direction y, as shown in FIGS. 18 and 19. As shown in FIGS. 20 and 23, each fifth lead 25 has an end face 251 facing the third direction y. The end face 251 of each fifth lead 25 is exposed from a corresponding one of the two third side surfaces 55 of the sealing resin 50.

Next, some of the advantages of the semiconductor device A40 will be described.

The semiconductor device A40 comprises a first lead 21 including a first pad portion 211, a first semiconductor element 11, a plurality of first wires 41, and a sealing resin 50. Each first wire 41 has a first bonding portion 411 and a second bonding portion 412. The first wire 41 is provided with a first protrusion 413 covered by the sealing resin 50, while also overlapping the second bonding portion 412. The first pad portion 211 is formed with a first hole 214. The first hole 214 is positioned closer to the second bonding portions 412 than to the first bonding portions 411. The first hole 214 extends vertically from the first mount surface 211A of the first pad portion 211 and penetrates throughout the first pad portion 211 in the first direction z. A portion of the sealing resin 50 is accommodated in the first hole 214. Thus, in the semiconductor device A40 as well, detachment of the first wire(s) 41 from the first pad portion 211 can be suppressed. Furthermore, the semiconductor device A40 can enjoy the same advantages as the semiconductor device A10 by having a configuration common to that of the semiconductor device A10.

The present disclosure is not limited to the embodiments/variations described above. The configuration of each part of the present disclosure may be varied in many ways.

The present disclosure includes the embodiments described in the following clauses.

Clause 1. A semiconductor device comprising:

a first lead including a first pad portion having a first mount surface facing one side in a first direction;

a first semiconductor element bonded to the first mount surface;

a first wire conductively bonded to the first semiconductor element and the first mount surface; and

a sealing resin covering at least a part of the first pad portion, the first semiconductor element, and the first wire,

wherein the first wire includes a first bonding portion conductively bonded to the first semiconductor element and a second bonding portion conductively bonded to the first mount surface,

the first wire is provided with a first protrusion that overlaps the second bonding portion and is covered by the sealing resin,

the first pad portion is formed with a first hole disposed closer to the second bonding portion than to the first bonding portion, the first hole extending from the first mount surface and penetrating throughout the first pad portion in the first direction,

a part of the sealing resin is disposed in the first hole.

Clause 2. The semiconductor device according to clause 1, wherein the first protrusion is in contact with the second bonding portion and the first mount surface.

Clause 3. The semiconductor device according to clause 2, wherein as viewed in the first direction, the first wire overlaps with the first hole.

Clause 4. The semiconductor device according to clause 3, wherein as viewed in the first direction, the first hole extends in a direction perpendicular to a direction in which the first wire extends.

Clause 5. The semiconductor device according to clause 2, wherein as viewed in the first direction, the first wire is spaced apart from the first hole.

Clause 6. The semiconductor device according to clause 5, wherein as viewed in the first direction, the first hole is disposed between the first bonding portion and the second bonding portion.

Clause 7. The semiconductor device according to clause 5, wherein as viewed in the first direction, the first hole is disposed to one side of the second bonding portion in a direction perpendicular to a direction in which the first wire extends.

Clause 8. The semiconductor device according to clause 5, wherein the first hole includes a first part (first sub-hole) and a second part (second sub-hole) spaced apart from each other,

as viewed in the first direction, the first part and the second part are disposed to opposite sides of the second bonding portion, respectively, in a direction perpendicular to a direction in which the first wire extends.

Clause 9. The semiconductor device according to clause 2, wherein the first wire includes a main portion between the first bonding portion and the second bonding portion,

a dimension of the first protrusion in a direction perpendicular to the first direction is greater than a dimension of the main portion in a direction perpendicular to a direction in which the first wire extends.

Clause 10. The semiconductor device according to clause 9, wherein a dimension of the first protrusion in a direction perpendicular to the first direction is greater than a dimension of the first bonding portion in the direction perpendicular to the first direction.

Clause 11. The semiconductor device according to any of clauses 2 to 10, further comprising: a second lead; and a second wire conductively bonded to the first semiconductor element and the second lead, wherein the second wire is covered by the sealing resin,

the sealing resin has a first side surface facing one side in a second direction perpendicular to the first direction,

the second lead protrudes from the first side surface.

Clause 12. The semiconductor device according to clause 11, wherein the second wire includes a third bonding portion conductively bonded to the second lead,

the second wire is provided with a second protrusion overlapping the third bonding portion and being covered by the sealing resin.

Clause 13. The semiconductor device according to clause 11, wherein the first lead includes a first terminal portion and a first support portion each connected to the first pad portion,

the first terminal portion protrudes from the first side surface,

the first support portion is connected to the first pad portion at one side of the first pad portion in the second direction and exposed from the first side surface.

Clause 14. The semiconductor device according to clause 13, wherein the first pad portion has a first back surface facing away from the first mount surface in the first direction,

the first pad portion is provided with a first recess recessed from the first back surface,

a part of the sealing resin is disposed in the first recess.

Clause 15. The semiconductor device according to clause 14, wherein as viewed in the first direction, the second bonding portion is spaced apart from the first recess.

Clause 16. The semiconductor device according to clause 15, wherein the first recess is continuous with the first hole.

Clause 17. The semiconductor device according to clause 14, further comprising:

a third lead including a second pad portion having a second mount surface facing the same side as the first mount surface in the first direction;

a second semiconductor element bonded to the second mount surface; and

a third wire conductively bonded to the first semiconductor element and the second semiconductor element,

wherein the second pad portion is spaced apart from the first pad portion in the second direction,

at least a portion of the second pad portion, the second semiconductor element, and the third wire are covered by the sealing resin.

Clause 18. The semiconductor device according to clause 17, further comprising:

a fourth lead; and

a fourth wire conductively bonded to the second semiconductor element and the fourth lead,

wherein the fourth lead is covered by the sealing resin,

the sealing resin has a second side surface facing away from the first side surface in the second direction,

the fourth lead protrudes from the second side surface.

Clause 19. The semiconductor device according to clause 18, wherein the third lead includes a second terminal portion and a second support portion each connected to the second pad portion,

the second terminal portion protrudes from the second side surface,

the second support portion is disposed opposite from the first pad portion in the second direction with respect to the second pad portion and exposed from the second side surface.

Clause 20. The semiconductor device according to clause 19, further comprising a fifth wire conductively bonded to the second semiconductor element and the second mount surface,

wherein the fifth wire is covered by the sealing resin,

the fifth wire includes a fifth bonding portion conductively bonded to the second semiconductor element and a sixth bonding portion conductively bonded to the second mount surface,

the fifth wire is provided with a fourth protrusion overlapping the sixth bonding portion and covered by the sealing resin,

the second pad portion is formed with a second hole disposed closer to the sixth bonding portion than to the fifth bonding portion, the second hole extending from the second mount surface and penetrating through the second pad portion in the first direction,

a part of the sealing resin is disposed in the second hole.

Clause 21. The semiconductor device according to clause 20, wherein as viewed in the first direction, the fifth wire overlaps with the second hole.

Clause 22. The semiconductor device according to clause 21, further comprising two fifth leads spaced apart from each other in a third direction perpendicular to the first direction and the second direction,

the sealing resin has two third side surfaces facing away from each other in the third direction,

the two fifth leads are exposed from the two third side surfaces, respectively.

Clause 23. The semiconductor device according to clause 22, wherein as viewed in the second direction, the two fifth leads overlap with one of the first terminal portion and the second terminal portion.

Clause 24. The semiconductor device according to clause 14, wherein the sealing resin has a top surface facing the same side as the first mount surface in the first direction and a bottom surface facing away from the top surface in the first direction,

a dimension of the sealing resin from the top surface to the first mount surface in the first direction is greater than a dimension of the sealing resin from the bottom surface to the first back surface in the first direction.

Clause 25. The semiconductor device according to clause 24, wherein the first side surface includes a first region containing the first direction as an in-plane direction, a second region disposed between the first region and the top surface in the first direction, and a third region disposed opposite from the second region with respect to the first region,

the second region and the third region are each inclined relative to the first region,

the first terminal portion and the second lead protrude from the first region,

the first support is exposed from the first region.

Clause 26. The semiconductor device according to clause 25, wherein an inclination angle of the second region relative to the first region is greater than an inclination angle of the third region relative to the first region.

Clause 27. The semiconductor device according to clause 11, wherein the second lead includes a first connecting surface facing the same side as the first mount surface in the first direction and covered by the sealing resin, and a first mounting surface facing away from the first connecting surface in the first direction and exposed from the sealing resin,

the second wire is conductively bonded to the first connecting surface,

the first mounting surface is located furthest from the first connecting surface in the first direction,

the sealing resin has a bottom surface facing away from the first mount surface in the first direction,

the first mounting surface protrudes beyond a virtual plane containing the bottom surface.

Clause 28. The semiconductor device according to clause 27, wherein the first mounting surface is inclined relative to the bottom surface.

1. A semiconductor device comprising:
a first lead including a first pad portion having a first mount surface facing one side in a first direction;
a first semiconductor element bonded to the first mount surface;
a first wire conductively bonded to the first semiconductor element and the first mount surface; and
a sealing resin covering the first semiconductor element, the first wire, and at least a part of the first pad portion,
wherein the first wire includes a first bonding portion conductively bonded to the first semiconductor element and a second bonding portion conductively bonded to the first mount surface;
the first wire is provided with a first protrusion overlapping the second bonding portion and being covered by the sealing resin,
the first pad portion is formed with a first hole disposed closer to the second bonding portion than to the first bonding portion, the first hole extending from the first mount surface and penetrating through the first pad portion in the first direction,
a part of the sealing resin is disposed in the first hole.

2. The semiconductor device according to claim 1, wherein the first protrusion is in contact with the second bonding portion and the first mount surface.

3. The semiconductor device according to claim 2, wherein as viewed in the first direction, the first wire overlaps with the first hole.

4. The semiconductor device according to claim 3, wherein as viewed in the first direction, the first hole extends in a direction perpendicular to a direction in which the first wire extends.

5. The semiconductor device according to claim 2, wherein as viewed in the first direction, the first wire is spaced apart from the first hole.

6. The semiconductor device according to claim 5, wherein as viewed in the first direction, the first hole is disposed between the first bonding portion and the second bonding portion.

7. The semiconductor device according to claim 5, wherein as viewed in the first direction, the first hole is disposed to one side of the second bonding portion in a direction perpendicular to a direction in which the first wire extends.

8. The semiconductor device according to claim 5, wherein the first hole includes a first part and a second part spaced apart from each other,
as viewed in the first direction, the first part and the second part are disposed to opposite sides of the second bonding portion, respectively, in a direction perpendicular to a direction in which the first wire extends.

9. The semiconductor device according to claim 2, wherein the first wire includes a main portion between the first bonding portion and the second bonding portion,
a dimension of the first protrusion in a direction perpendicular to the first direction is greater than a dimension of the main portion in a direction perpendicular to a direction in which the first wire extends.

10. The semiconductor device according to claim 9, wherein a dimension of the first protrusion in a direction perpendicular to the first direction is greater than a dimension of the first bonding portion in the direction perpendicular to the first direction.

11. The semiconductor device according to claim 2, further comprising:
a second lead; and
a second wire conductively bonded to the first semiconductor element and the second lead,
the second wire is covered by the sealing resin,
the sealing resin has a first side surface facing one side in a second direction perpendicular to the first direction,
the second lead protrudes from the first side surface.

12. The semiconductor device according to claim 11, wherein the second wire includes a third bonding portion conductively bonded to the second lead,
the second wire is provided with a second protrusion overlapping the third bonding portion and covered by the sealing resin.

13. The semiconductor device according to claim 11, wherein the first lead includes a first terminal portion and a first support portion each connected to the first pad portion,
the first terminal portion protrudes from the first side surface,
the first support portion is connected to the first pad portion at one side of the first pad portion in the second direction and exposed from the first side surface.

14. The semiconductor device according to claim 13, wherein the first pad portion has a first back surface facing away from the first mount surface in the first direction,
the first pad portion is provided with a first recess recessed from the first back surface,
a part of the sealing resin is disposed in the first recess.

15. The semiconductor device according to claim 14, wherein as viewed in the first direction, the second bonding portion is spaced apart from the first recess.

16. The semiconductor device according to claim 15, wherein the first recess is continuous with the first hole.

17. The semiconductor device according to claim 14, further comprising:
a third lead including a second pad portion having a second mount surface facing the same side as the first mount surface in the first direction;
a second semiconductor element bonded to the second mount surface; and
a third wire conductively bonded to the first semiconductor element and the second semiconductor element,
the second pad portion is spaced apart from the first pad portion in the second direction,
the second semiconductor element, the third wire, and at least a part of the second pad portion are covered by the sealing resin.

18. The semiconductor device according to claim 14, further comprising:
a fourth lead; and
a fourth wire conductively bonded to the second semiconductor element and the fourth lead,
the fourth wire is covered by the sealing resin,
the sealing resin has a second side surface facing away from the first side surface in the second direction,
the fourth lead protrudes from the second side surface.
